(19) United States
(12) Patent Application Publication
(10) Pub. No.: US 2017/0170336 A1
(43) Pub. Date: Jun. 15, 2017

(54) SYSTEMS AND METHODS FOR ROUTING WIRES IN A SOLAR MODULE

(71) Applicant: SolarCity Corporation, San Mateo, CA (US)

(72) Inventors: Bobby Yang, Los Altos Hills, CA (US); Lilja Magnusdottir, San Rafael, CA (US); Peter Nguyen, San Jose, CA (US)

(21) Appl. No.: 14/985,338

(22) Filed: Dec. 30, 2015

Related U.S. Application Data
(60) Provisional application No. 62/267,239, filed on Dec. 14, 2015.

(51) Int. Cl. H01L 31/02; H02S 40/34; H01L 31/05

(52) U.S. Cl. CPC H01L 31/0201; H01L 31/0504; H02S 40/34

(57) ABSTRACT

A solar module that includes multiple series-connected sub-circuits is provided. Each sub-circuit may include multiple solar cell strings coupled in parallel. The sub-circuits may be coupled to a junction box that includes bypass diodes. Each of the sub-circuits may be coupled in parallel with a respective bypass diode in the junction box. The sub-circuits may be coupled to the junction box via interconnect buses. The interconnect buses may be routed to an entry point from only one side the junction box to improve manufacturability. The interconnect buses may also include one or more bends to provide strain relief during normal operation of the solar module and during thermal cycling events.

### REFERENCE TO RELATED APPLICATIONS

This application claims the benefit of U.S. Provisional Application No. 62/267,239, filed on Dec. 14, 2015, which is incorporated by reference herein.

### BACKGROUND

Field

This disclosure is generally related to the fabrication of solar cells.

Background

The negative environmental impact of fossil fuels and their rising cost have resulted in a dire need for cleaner, cheaper alternative energy sources. Among different forms of alternative energy sources, solar power has been favored for its cleanness and wide availability.

A solar cell converts light into electricity using the photovoltaic effect. There are several basic solar cell structures, including a single p-n junction, p-i-n/n-i-p, and multi-junction. A typical single p-n junction structure includes a p-type doped layer and an n-type doped layer. Solar cells with a single p-n junction can be homojunction solar cells or heterojunction solar cells. If both the p-doped and n-doped layers are made of similar materials (materials with equal band gaps), the solar cell is called a homojunction solar cell. In contrast, a heterojunction solar cell includes at least two layers of materials of different bandgaps. A p-i-n/n-i-p structure includes a p-type doped layer, an n-type doped layer, and an intrinsic (undoped) semiconductor layer (the i-layer) sandwiched between the p-layer and the n-layer. A multi junction structure includes multiple single-junction structures of different bandgaps stacked on top of one another.

A solar panel typically includes an array of solar cells connected in series or parallel. The array of solar cells is connected to a junction box mounted on the solar panel. In particular, the array of solar cells may be connected to the mounted junction box via only straight interconnect wires. These straight interconnect wires are, however, especially prone to cracking that can arise from thermal cycling and temperature variation during normal operation of the solar panel. In some configurations, straight wires are routed to two different sides (or entry points) of the junction box. The need to make connections at more than one entry point at the junction box also unnecessary increases manufacturing complexity.

It would therefore be desirable to provide improved solar panels that are more resilient to thermal stress.

### SUMMARY

In one embodiment, a solar module is provided. The solar module may include a plurality of sub-circuits, a junction box mounted on the solar module, and interconnect buses connecting the plurality of sub-circuits to only one edge (or entry point) of the junction box. Each sub-circuit may include multiple solar cell strings coupled in parallel.

As an example, the solar panel may include four sub-circuits connected in series. Each of the four sub-circuits may include three strings of solar cells coupled in parallel. In particular, a first sub-circuit may be coupled between a first node and a second node, a second sub-circuit may be coupled between the second node and a third node, a third sub-circuit may be coupled between the third node and a fourth node, a fourth sub-circuit may be coupled between the fourth node and a fifth node.

The junction box may include five ports that are coupled to a respective one of the five nodes. In one suitable arrangement, the first and fifth node may be coupled to the first and fifth ports of the junction box via buses with a U-shaped bend (sometimes referred to as J-buses). The second, third, and fourth nodes may be coupled to the second, third, and fourth ports of the junction box via buses with one or more bends. Configured in this way, the bends help provide stress relief for the routing buses during thermal cycle events, which can help prevent damage to the routing buses. In general, the routing buses may have the same number of bends or different number of bends. Each routing bus may include at least one U-shaped bend, at least one L-shaped bend, at least one Z-shaped bend, or any suitable number of bends to help optimize stress relief.

Further features of the invention, its nature and various advantages will be more apparent from the accompanying drawings and following detailed description.

### BRIEF DESCRIPTION OF THE DRAWINGS

FIG. 1 shows a cross-sectional side view of a conventional solar cell.

FIG. 2 shows a cross-sectional side view of an illustrative double-sided tunneling junction solar cell according to one embodiment.

FIG. 3A shows a top view illustrating the electrode grid of a conventional solar cell.

FIG. 3B shows a top view illustrating the front or back surface of an exemplary bifacial solar cell with a single center busbar for each surface according to one embodiment.

FIG. 3C shows a cross-sectional side view of an illustrative bifacial solar cell with a single center busbar on each of the front and back surfaces according to one embodiment.

FIG. 3D is a diagram showing the front surface of an exemplary bifacial solar cell according to one embodiment.

FIG. 3E is a diagram showing the back surface of an exemplary bifacial solar cell according to one embodiment.

FIG. 3F shows a cross-sectional side view of an exemplary bifacial solar cell with a single edge busbar on each of the top and bottom surfaces according to one embodiment.

FIG. 4 is a diagram of a simplified equivalent circuit of a solar module with serially connected solar cells.

FIG. 5 is a diagram of a simplified equivalent circuit of a solar module with parallelly connected solar cells according to one embodiment.

FIG. 6 is a diagram showing three solar cell strings coupled in parallel according to one embodiment.

FIG. 7 is a diagram of a string of solar cells, where each solar cell in the string are divided into multiple smaller cells according to one embodiment.

FIG. 8A shows a cross-sectional side view of three adjacent smaller cells that are serially connected via single edge busbars according to one embodiment.

FIG. 8B shows a bottom view of the three adjacent smaller cells of FIG. 8A according to one embodiment.

FIG. 9 is a diagram of an exemplary solar module having three solar cell strings coupled in parallel, where each solar cell are divided into multiple smaller cells, according to one embodiment.

FIG. 10 is a diagram of an exemplary solar module that includes four sub-circuits coupled to a junction box according to one embodiment.

FIG. 11 is a diagram showing how the four sub-circuits in the exemplary solar module of FIG. 10 can be coupled to a junction box via straight interconnects from both sides of the junction box according to one embodiment.

FIG. 12 is a diagram showing how the four sub-circuits in the exemplary solar module of FIG. 10 can be coupled to a junction box from only one side of the junction box according to one embodiment.

FIG. 13A is a diagram showing how the four sub-circuits in the exemplary solar module of FIG. 10 can be coupled to a junction box from only the left side of the junction box via interconnects with multiple bends to help provide strain relief according to one embodiment.

FIG. 13B is a diagram showing how the J-buses may also be provided with strain relief features according to one embodiment.

FIG. 13C is a diagram showing how the four sub-circuits in the exemplary solar module of FIG. 10 can be coupled to a junction box from only the right side of the junction box via interconnects with multiple bends to help provide strain relief according to one embodiment.

FIG. 13D is a diagram showing how the four sub-circuits in the exemplary solar module of FIG. 10 can be coupled to a junction box from only the top side of the junction box via interconnects with multiple bends to help provide strain relief according to one embodiment.

FIG. 13E is a diagram showing how the four sub-circuits in the exemplary solar module of FIG. 10 can be coupled to a junction box from two sides of the junction box via interconnects with multiple bends to help provide strain relief according to one embodiment.

FIG. 13F is a diagram showing how the four sub-circuits in the exemplary solar module of FIG. 10 can be coupled to a junction box from three sides of the junction box via interconnects with multiple bends to help provide strain relief according to one embodiment.

FIG. 13G is a diagram showing how the four sub-circuits in the exemplary solar module of FIG. 10 can be coupled to a junction box from all four sides of the junction box via interconnects with multiple bends to help provide strain relief according to one embodiment.

FIG. 14 is a diagram of an exemplary solar module that is divided into n sub-circuits, each of which is coupled to a junction box via interconnects with any suitable number of bends to provide strain relief according to one embodiment.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments herein provide a high-efficiency solar module, sometimes referred to as a solar “panel.” Note that a large solar array often includes individual solar panels that are connected in parallel. Typically, a series-connected set of solar cells within a panel is called a “string,” and a set of parallel connected strings is called a “block.” To reduce the portion of power that is consumed by the internal resistance of a solar module, the present inventive solar module includes solar cell strings coupled in parallel. Moreover, to ensure the output compatibility between the present inventive solar module and a conventional solar module, each conventional square-shaped cell, after the device structure is fabricated, is divided into a number of cut cells, which can be rectangular-shaped strips and can be serially coupled, so that the entire module outputs substantially the same open-circuit voltage as a conventional module.

In one suitable arrangement, the solar cells in the solar module may be grouped into four sub-circuits, each of which includes multiple solar cell strings coupled in parallel. Each sub-circuit may include the same or a different number of solar cells. The four sub-circuits may be coupled in series to an associated junction box. For example, a first sub-circuit may have a first terminal that is directly coupled to the junction box; the first sub-circuit may have a second terminal that is directly coupled to a second sub-circuit via a first intermediate node; the second sub-circuit may be coupled to a third sub-circuit via a second intermediate node; the third sub-circuit may be coupled to a first terminal of a fourth sub-circuit via a third intermediate node; and the fourth sub-circuit may have a second terminal that is directly coupled to the junction box

The junction box may include diodes to help bypass defective solar cell strings. To ensure that each of the sub-circuits is provided with a respective bypass diode, the first, second, and third intermediate nodes should be coupled to the junction box via interconnects traversing different portions of the solar module.

In one embodiment, the interconnects may be straight and may be coupled to at least two sides of the junction box.

In another suitable embodiment, at least some of the interconnects may be bent, which allows the interconnects to be coupled to the junction box from only one side. Allowing connections from only one side of the junction box can help simplify and improve manufacturability.

In yet another suitable embodiment, at least some of the longer interconnects may include multiple bends, which help to alleviate mechanical stress that the interconnects may experience during fabrication and during normal operation.

### Bifacial Tunneling Junction Solar Cells

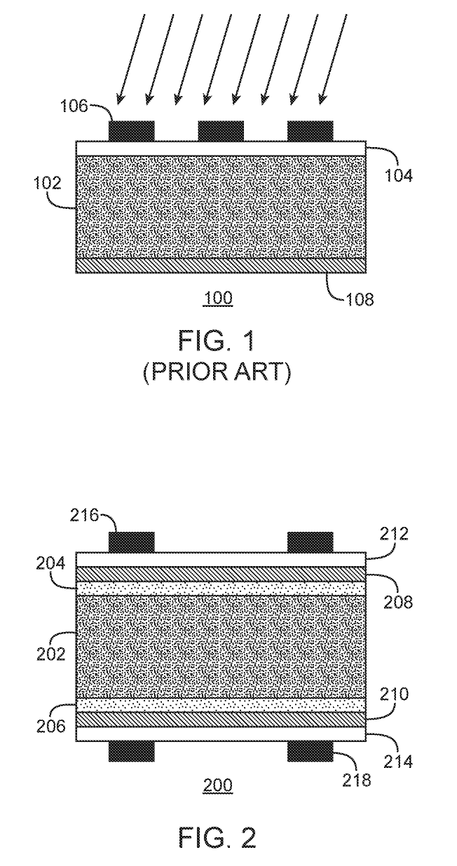

FIG. 1 shows a diagram of a conventional solar cell 100. Solar cell 100 includes an n-type doped Si substrate 102, a p⁺ silicon emitter layer 104, a front electrode grid 106, and an Aluminum (Al) back electrode 108. Arrows in FIG. 1 indicate incident sunlight. As shown in FIG. 1, Al back electrode 108 covers the entire backside of solar cell 100, hence preventing light absorption at the backside. Moreover, front electrode grid 106 often includes a metal grid that is opaque to sunlight and casts a shadow on the front surface of solar cell 100. For conventional solar cell 100, the front electrode grid can block up to 8% of the incident sunlight, thus significantly reducing the conversion efficiency.

FIG. 2 shows an exemplary double-sided tunneling junction solar cell, in accordance with an embodiment of the present invention. Double-sided tunneling junction solar cell 200 can include substrate 202, quantum tunneling barrier (QTB) layers 204 and 206 covering both surfaces of substrate 202 and passivating the surface-defect states, front-side doped a-Si layer forming a front emitter 208, back-side doped a-Si layer forming a back surface field (BSF) layer 210, front transparent conducting oxide (TCO) layer 212, back TCO layer 214, front metal grid 216, and back metal grid 218. Note that it is also possible to have the emitter layer at the backside and a front surface field (FSF) layer at the front side of the solar cell. Details, including fabrication methods, about double-sided tunneling junction solar cell 200 can be found in U.S. patent application Ser. No. 12/945,792, entitled “Solar Cell with Oxide Tunneling Junctions,” by Jiunn Benjamin Heng, Chentao Yu, Zheng Xu, and Jianming Fu, filed 12 Nov. 2010, the disclosure of which is incorporated by reference in its entirety herein.

As one can see from FIG. 2, the symmetric structure of double-sided tunneling junction solar cell 200 ensures that double-sided tunneling junction solar cell 200 can be bifacial given that the backside is exposed to light. In solar cells, the metallic contacts, such as front and back metal grids 216 and 218, are necessary to collect the current generated by the solar cell. In general, a metal grid includes two types of metal lines, including busbars and fingers. More specifically, busbars are wider metal strips that are connected directly to external leads (such as metal tabs), while fingers are finer areas of metallization which collect current for delivery to the busbars. The key design trade-off in the metal grid design is the balance between the increased resistive losses associated with a widely spaced grid and the increased reflection and shading effect caused by a high fraction of metal coverage of the surface.

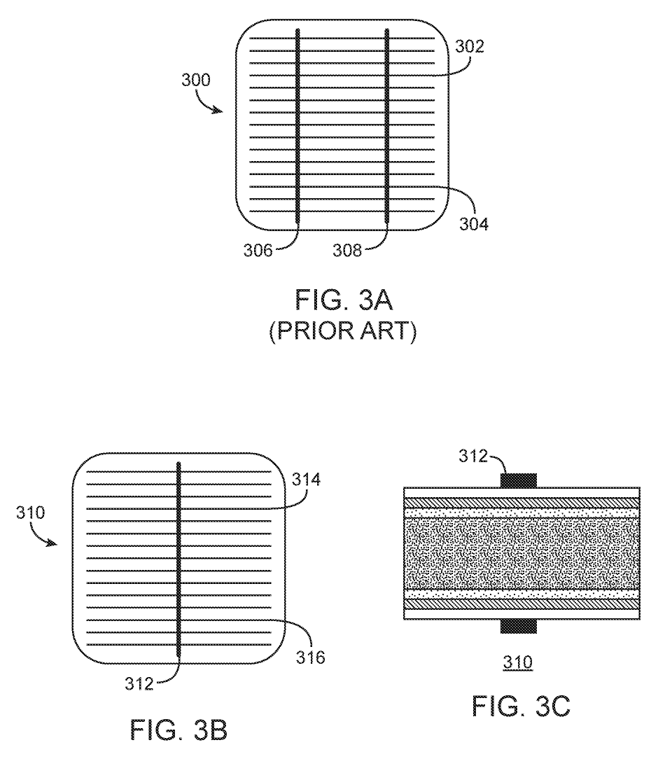

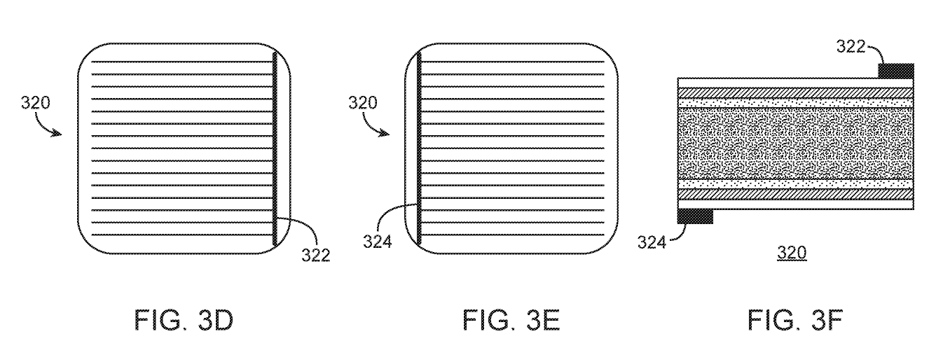

In conventional solar cells, to prevent power loss due to series resistance of the fingers, at least two busbars are placed on the surface of the solar cell to collect current from the fingers, as shown in FIG. 3A. For standardized 5-inch solar cells (which can be 5×5 inch squares or pseudo squares with beveled corners), there are typically two busbars at each surface. For larger, 6-inch solar cells (which can be 6×6 inch² squares or pseudo squares), three or more busbars may be needed depending on the resistivity of the electrode materials. Note that in FIG. 3A a surface (which can be the front or back surface) of solar cell 300 can include a plurality of parallel finger lines, such as finger lines 302 and 304, and two busbars 306 and 308 placed perpendicular to the finger lines. Note that the busbars are placed in such a way as to ensure that the distance (and hence the resistance) from any point on a finger to a busbar is small enough to minimize power loss. However, these two busbars and the metal ribbons that are later soldered onto these busbars for inter-cell connections can create a significant amount of shading, which degrades the solar cell performance.

In some embodiments, the front and back metal grids, such as the finger lines, can include electroplated Cu lines, which have reduced resistance compared with conventional Ag grids. For example, using an electroplating or electroless plating technique, one can obtain Cu grid lines with a resistivity of equal to or less than 5×10⁻⁶ Ω·cm. Details about an electroplated Cu grid can be found in U.S. patent application Ser. No. 12/835,670, entitled “Solar Cell with Metal Grid Fabricated by Electroplating,” by Jianming Fu, Zheng Xu, Chentao Yu, and Jiunn Benjamin Heng, filed 13 Jul. 2010; and U.S. patent application Ser. No. 13/220,532, entitled “Solar Cell with Electroplated Metal Grid,” by Jianming Fu, Jiunn Benjamin Heng, Zheng Xu, and Chentao Yu, filed 29 Aug. 2011, the disclosures of which are incorporated by reference in their entireties herein.

The reduced resistance of the Cu fingers makes it possible to have a metal grid design that maximizes the overall solar cell efficiency by reducing the number of busbars on the solar cell surface. In some embodiments of the present invention, a single busbar is used to collect finger current. The power loss caused by the increased distance from the fingers to the busbar can be balanced by the reduced shading.

FIG. 3B shows the front or back surface of an exemplary bifacial solar cell with a single center busbar per surface, in accordance with an embodiment of the present invention. As shown in FIG. 3B, the front or back surface of solar cell 310 can include a single busbar 312 and a number of finger lines, such as finger lines 314 and 316.

FIG. 3C shows a cross-sectional view of the bifacial solar cell with a single center busbar per surface, in accordance with an embodiment of the present invention. The semiconductor multilayer structure shown in FIG. 3C can be similar to the one shown in FIG. 2. Note that the finger lines are not shown in FIG. 3C because the cut plane cuts between two finger lines. In the example shown in FIG. 3C, busbar 312 runs in and out of the paper, and the finger lines run from left to right. As discussed previously, because there is only one busbar at each surface, the distances from the edges of the fingers to the busbar are longer. However, the elimination of one busbar reduces shading, which not only compensates for the power loss caused by the increased finger-to-busbar distance, but also provides additional power gain. For a standard sized solar cell, replacing two busbars with a single busbar in the center of the cell can produce a 1.8% power gain.

FIG. 3D shows the front surface of an exemplary bifacial solar cell, in accordance with an embodiment of the present invention. In FIG. 3D, the front surface of solar cell 320 includes a number of horizontal finger lines and vertical single busbar 322, which is placed at the right edge of solar cell 320. More specifically, busbar 322 is in contact with the rightmost edge of all the finger lines, and collects current from all the finger lines.

FIG. 3E shows the back surface of an exemplary bifacial solar cell, in accordance with an embodiment of the present invention. In FIG. 3E, the back surface of solar cell 320 includes a number of horizontal finger lines and vertical single busbar 324, which is placed at the left edge of solar cell 320. Similar to busbar 322, single busbar 324 is in contact with the leftmost edge of all the finger lines.

FIG. 3F shows a cross-sectional side view of the bifacial solar cell with a single edge busbar per surface, in accordance with an embodiment of the present invention. The semiconductor multilayer structure shown in FIG. 3F can be similar to the one shown in FIG. 2. Like FIG. 3C, in FIG. 3F, the finger lines (not shown) run from left to right, and the busbars run in and out of the paper. From FIGS. 3D-3F, one can see that in this embodiment, the busbars on the front and the back surfaces of the bifacial solar cell are placed at the opposite edges of the cell. This configuration can further improve power gain because the busbar-induced shading now occurs at locations that were less effective in energy production. In general, the edge-busbar configuration can provide at least a 2.1% power gain.

Note that the single busbar per surface configurations (either the center busbar or the edge busbar) not only can provide power gain, but also can reduce fabrication cost, because less metal will be needed for busing ribbons. Moreover, in some embodiments of the present invention, the metal grid on the front sun-facing surface can include parallel metal lines (such as fingers), each having a cross-section with a curved parameter to ensure that incident sunlight on these metal lines is reflected onto the front surface of the solar cell, thus further reducing shading. Such a shade-free front electrode can be achieved by electroplating Ag- or Sn-coated Cu, or the like, using a well-controlled, cost-effective patterning scheme.

### Solar Module Layout

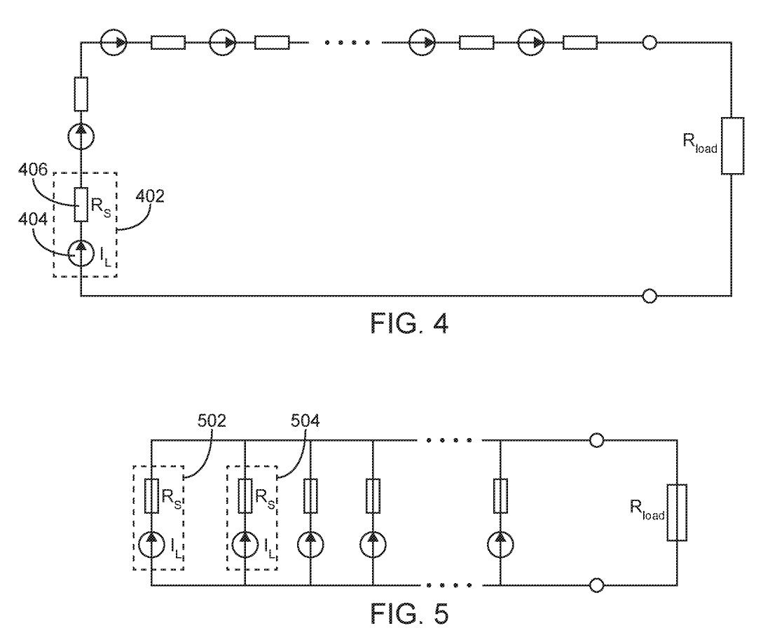

FIG. 4 shows a simplified equivalent circuit of a solar module (sometimes referred to as a solar panel) with serially connected solar cells. In FIG. 4, each solar cell is represented by a current source with an internal resistance. For example, solar cell 402 is represented by current source 404 coupled in series with resistor 406. When a solar panel includes serially connected solar cells as shown in FIG. 4, the output power of the entire panel is determined by the total generated current V_{L}_{_}ₜₒₜₐₗ) and the sum of total internal resistance (Rₛ_{_}ₜₒₜₐₗ) and external resistance (i.e., the load resistance, R_{load}). For example, if all solar cells are identical and receive the same amount of light, for n serially connected solar cells, I_{L}_{_}ₜₒₜₐₗ=I_{L} and Rₛ_{_}ₜₒₜₐₗ=nRₛ, and the total power generated by the entire circuit can be calculated as Pₒᵤₜ=I_{L}²×(Rₛ_{_}ₜₒₜₐₗ+R_{load}). Assuming that the load resistance R_{load} is adjusted by a maximum power point tracking (MPPT) circuit such that the total resistance for the entire circuit (Rₛ_{_}ₜₒₜₐₗ+R_{load}) allows the entire panel to operate at the maximum power point (which means at a fixed I_{L}_{_}ₜₒₜₐₗ), the amount of power extracted to the external load depends on the total internal resistance Rₛ_{_}ₜₒₜₐₗ. In other words, a portion of the generated power is consumed by the serial internal resistance in the solar cells themselves: P_{R}=I_{L}²×nRₛ. In other words, the less the total internal resistance the entire panel has, the less power is consumed by the solar cells themselves, and the more power is extracted to the external load.

One way to reduce the power consumed by the solar cells is to reduce the total internal resistance. Various approaches can be used to reduce the series resistance of the electrodes at the cell level. On the panel level, one effective way to reduce the total series resistance is to connect a number of cells in parallel, instead of connecting all the cells within a panel in series. FIG. 5 illustrates a simplified equivalent circuit of a solar panel with parallelly connected solar cells. In the example shown in FIG. 5, all solar cells, such as solar cells 502 and 504, are connected in parallel. As a result, the total internal resistance of the solar panel is Rₛ_{_}ₜₒₜₐₗ=Rₛ/n, which is much smaller than the resistance of each individual solar cell. However, the output voltage V_{load} is now limited by the open circuit voltage of a single solar cell, which is difficult in a practical setting to drive the load, although the output current can be n times the current generated by a single solar cell.

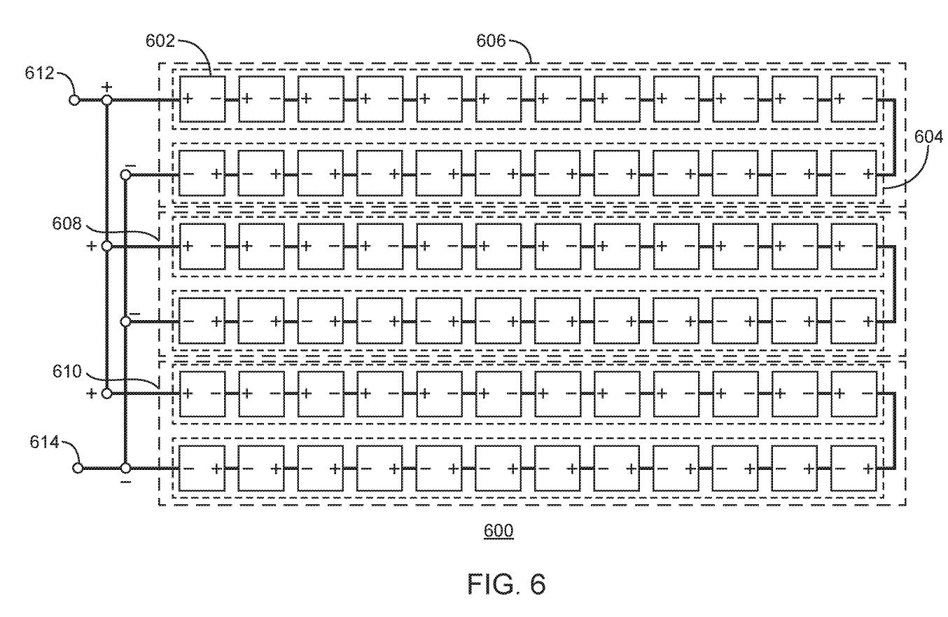

In order to attain an output voltage that is higher than that of the open circuit voltage of a single cell while reducing the total internal resistance for the panel, in some embodiments of the present invention, a subset of solar cells are connected into a string, and multiple strings are connected in parallel. FIG. 6 illustrates an exemplary solar panel configuration having multiple solar cell strings coupled in parallel. In the example shown in FIG. 6, solar panel 600 includes seventy-two solar cells arranged into six rows, such as top row 602 and second row 604, with each row including twelve cells. Each solar cell can be the standard 5- or 6-inch cell. For the purpose of illustration, each solar cell is marked with its anode and cathode on its edges, although in practice the anode and cathode of a solar cell are on its top and bottom side.

In the example of FIG. 6, solar cells in top row 602 and second row 604 are connected in series to form U-shaped string 606. Similarly, the solar cells in the middle two rows are also connected in series to form U-shaped string 608, and the solar cells in the bottom two rows are connected in series as well to form U-shaped string 610. Three U-shaped strings 606, 608, and 610 are then connected to each other in parallel. More specifically, the positive outputs of all three strings are coupled together to form positive output 612 of solar panel 600, whereas the negative outputs of all strings are coupled together to form negative output 614 of solar panel 600.

By serially connecting solar cells in subsets to form strings and then parallelly connecting the strings, one can reduce the serial resistance of the solar panel to a fraction of that of a conventional solar panel with all the cells connected in series. In the example shown in FIG. 6, the cells on a panel are divided into three strings (two rows in each string) and the three strings are parallelly connected, resulting in the total internal resistance of solar panel 600 being 1/9 of a conventional solar panel that has all of its seventy-two cells connected in series. The reduced total internal resistance decreases the amount of power consumed by the solar cells and allows more power to be extracted to external loads.

Parallelly connecting the strings also means that the output voltage of the panel is now the same as the voltage across each string, which is a fraction of the output voltage of a solar panel with all cells connected in series. In the example shown in FIG. 6, the output voltage of panel 600 is ⅓ of a solar panel that has all of its seventy-two cells connected in series.

Because the output voltage of each string is determined by the voltage across each solar cell (which is often slightly less than V_{oc}) and the number of serially connected cells in the string, one can increase the string output voltage by including more cells in each string. However, simply adding more cells in each row will result in an enlarged panel size, which is often limited due to various mechanical factors. Note that the voltage across each cell is mostly determined by V_{oc}, which is independent of the cell size. Hence, it is possible to increase the output voltage of each string by dividing each standard sized (5- or 6-inch) solar cell into multiple serially connected smaller cells. As a result, the output voltage of each string of solar cells is multiplied by the number of smaller cells in each solar cell in the string.

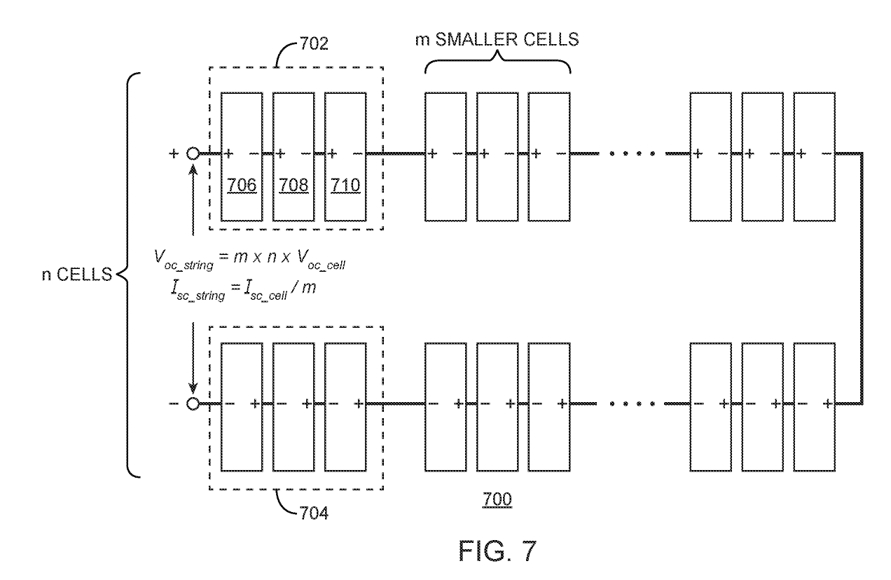

FIG. 7 is a diagram illustrating a solar cell string with each solar cell being divided into multiple smaller cells. In the example of FIG. 7, solar cell string 700 includes a number (m) of smaller cells. A conventional solar cell (such as the one represented by dotted line 702) is replaced by a number of serially connected smaller cells, such as cells 706, 708, and 710. For example, if the conventional solar cell is a 6-inch square cell, each smaller cell can have a dimension of 2-inch by 6-inch, and a conventional 6-inch square cell is replaced by three 2-inch by 6-inch smaller cells connected in series (e.g., m=3). Note that, as long as the layer structure of the smaller cells remains the same as the conventional square-sized solar cell, each smaller cell will have the same V_{oc} as that of the undivided solar cell 702. On the other hand, the current generated by each smaller cell is only a fraction of that of the original undivided cell due to its reduced size. Furthermore, the output current by solar cell string 700 is a fraction of the output current by a conventional solar cell string with undivided cells. The output voltage of the solar cell string is now three times that of a solar string with undivided cells, thus making it possible to have parallelly connected strings without sacrificing the output voltage.

Now assuming that the open circuit voltage (V_{oc}) across a standard 6-inch solar cell is V_{oc}_{_}_{cell}, then the V_{oc} of each string 700 is m×n×V_{oc}_{_}_{cell}, wherein m is the number of smaller cells as the result of dividing a conventional square shaped cell, and n is the number of conventional cells included in each string. On the other hand, assuming that the short circuit current (I_{sc}) for the standard 6-inch solar cell is I_{sc}_{_}_{cell}, then the I_{sc} of each string is I_{sc}_{_}_{cell}/m. Hence, when m such strings are connected in parallel in a new panel configuration, the V_{oc} for the entire panel will be the same as the V_{oc} for each string, and the I_{sc} for the entire panel will be the sum of the I_{sc} of all strings. More specifically, when m strings 700 are connected in parallel, one can achieve: V_{oc}_{_}ₚₐₙₑₗ=m×n×V_{oc}_{_}_{cell} and I_{sc}_{_}ₚₐₙₑₗ=I_{sc}_{_}_{cell}.

This means that the output voltage and current of this new solar panel will be comparable to the output voltage and current of a conventional solar panel of a similar size but with undivided solar cells all connected in series. The similar voltage and current outputs make this new panel compatible with other devices, such as inverters, that are used by a conventional solar panel with all its undivided cells connected in series. Although having similar current and voltage output, the new solar panel can extract more output power to external load because of the reduced total internal resistance.

Similar to the embodiment described in FIG. 3D-3F, a single tab that is as long as the long edge of the smaller cell and is between 3 and 12 mm in width can be used to connect two adjacent smaller cells. In some embodiments, the width of the single tab can be between 3 and 5 mm. Detailed descriptions of connecting two adjacent smaller cells using a single tab can be found in U.S. patent application Ser. No. 14/153,608, entitled “MODULE FABRICATION OF SOLAR CELLS WITH LOW RESISTIVITY ELECTRODES,” by Jiunn Benjamin Heng, Jianming Fu, Zheng Xu, and Bobby Yang and filed 13 Jan. 2014, the disclosure of which is incorporated by reference in its entirety herein.

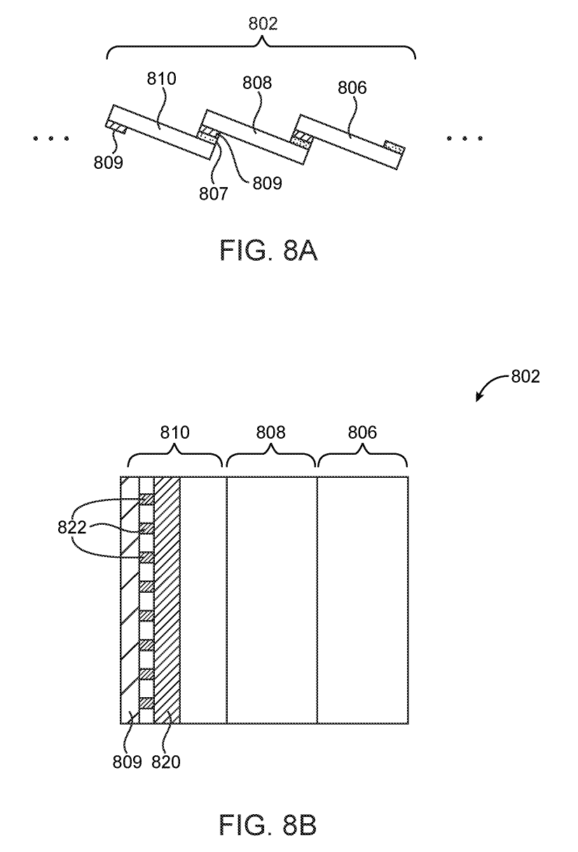

In addition to using a single tab to connect adjacent smaller cells in series, in some embodiments, the serial connection between adjacent smaller cells can be achieved by partially overlapping the adjacent smaller cells, thus resulting in the direct contact of the corresponding edge busbars. FIG. 8A is a cross-sectional side view illustrating the serial connection between three adjacent smaller cells with a single edge busbar per surface. In FIG. 8A, solar cell 802 may include first smaller cell 806 that is coupled to second smaller cell 808 via edge busbar 807 formed at the top surface of cell 806 and edge busbar 809 formed at the bottom surface of smaller cell 808. More specifically, the bottom surface of smaller cell 808 partially overlaps with the top surface of smaller cell 806 at the edge in such a way that bottom edge busbar 809 is placed on top of and in direct contact with top edge busbar 807. Solar cell 802 may also include third smaller cell 810 that is coupled to second smaller cell 808 via respective top and bottom surface edge busbars.

In some embodiments, the edge busbars that are in contact with each other are soldered together to enable the serial electrical connection between adjacent smaller cells. In further embodiments, the soldering may happen concurrently with a lamination process, during which the edge-overlapped smaller cells are placed in between a front-side cover and a back-side cover along with appropriate sealant material, which can include adhesive polymer, such as ethylene vinyl acetate (EVA). During lamination, heat and pressure are applied to cure the sealant, sealing the solar cells between the front-side and back-side covers. The same heat and pressure can result in the edge busbars that are in contact, such as edge busbars 807 and 809, being soldered together. Note that if the edge busbars include a top Sn layer, there is no need to insert additional soldering or adhesive materials between the top and bottom edge busbars (such as edge busbars 807 and 809) of adjacent solar cells. Also note that because the smaller cells are relatively flexible, the pressure used during the lamination process can be relatively large without the worry that the cells may crack under such pressure. In some embodiments, the pressure applied during the lamination process can be above 1.0 atmospheres, such as 1.2 atmospheres.

Such a string of smaller cells forms a pattern that is similar to roof shingles. Note that, in some embodiments, the three smaller cells shown in FIG. 8A are in fact parts of standard 6-inch square solar cell 802, with each smaller cell having a dimension of 2 inches by 6 inches. Compared with an undivided 6-inch solar cell, the partially overlapped smaller cells provide roughly the same photo-generation area but can lead to less power being consumed by the series resistance due to the reduced current. The overlapping should be kept to a minimum to minimize shading caused by the overlapping. The single busbars, both at the top and the bottom surface, are placed at the very edge of the smaller cell (as shown in FIG. 8A), thus minimizing the overlapping. The same shingle pattern can extend along all smaller cells in a row.

To ensure that smaller cells in two adjacent rows are connected in series, the two adjacent rows need to have opposite shingle patterns, such as right-side on top for one row and left-side on top for the adjacent row. Moreover, an extra wide metal tab can be used to serially connect the end smaller cells at the two adjacent rows. Detailed descriptions of serially connecting solar cells in a shingled pattern can be found in U.S. patent application Ser. No. 14/510,008, entitled “MODULE FABRICATION OF SOLAR CELLS WITH LOW RESISTIVITY ELECTRODES,” by Jiunn Benjamin Heng, Jianming Fu, Zheng Xu, and Bobby Yang and filed 8 Oct. 2014, the disclosure of which is incorporated by reference in its entirety herein.

Note that although the examples above illustrate adjacent solar cells being physically coupled with direct contact in a “shingling” configuration, in some embodiments of the present invention the adjacent solar cells can also be coupled electrically in series using conductive materials without being in direct contact with one another.

FIG. 8B shows a bottom view of solar cell 802 that is formed from three smaller cells 806, 808, and 810. In accordance with an embodiment, solar cell 806 may also include additional conductive lead 820 that is formed on the bottom surface of smaller cell 810 and that is coupled to edge busbar 809 formed on the same smaller cell 806 via comb-like shorting members 822. Configured in this way, conductive lead 820 provides an accessible tap point so that an electrical connection can be directly made to a particular solar cell 802 within a string of solar cells. Without lead 820, external electrical connections can only be made to the very front or the very end of a given solar cell string having smaller cells that are serially connected in the overlapping, shingling configuration.

If desired, additional lead 820 can also be formed on smaller cell 806 and/or cell 808. If leads 820 are also formed on cells 806 and 808, leads 820 can provide accessibility to each individual smaller cell in solar cell 802. To reduce cost and simplify manufacturing complexity, solar cell 802 may be provided with only one conductive lead 820 that accesses the bottom surface edge busbar 809 of only a selected one of the smaller cells (as shown in FIG. 8B). The example of FIG. 8B in which conductive lead 820 is formed on the bottom surface of smaller cell 810 is merely illustrative and does not serve to limit the scope of the present invention. If desired, conductive lead 820 can alternatively be formed on the top surface of any one of smaller cells 806, 808, and 810 within solar cell 802.

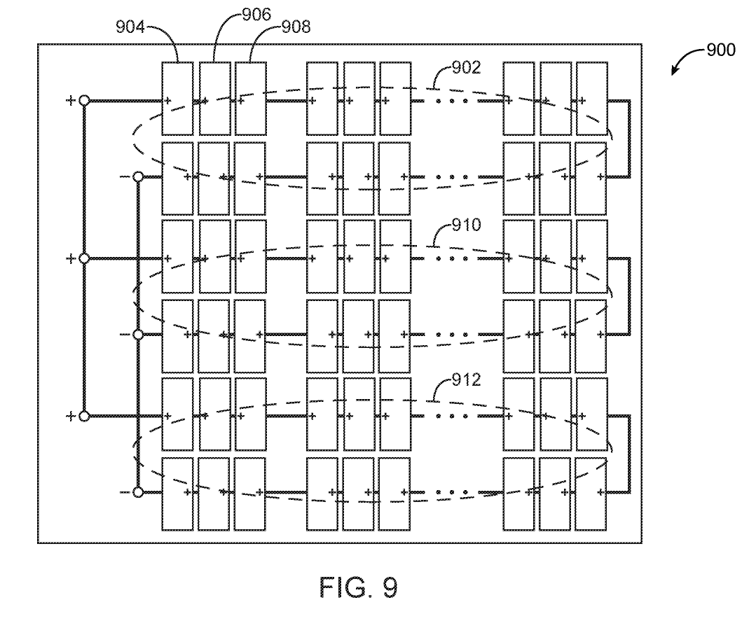

FIG. 9 shows exemplary solar module 900. In this example, solar module 900 may include arrays of solar cells that are arranged in a repeated pattern, such as a matrix that includes a plurality of rows. In some embodiments, solar panel 900 includes six rows of inter-connected smaller cells, with each row including thirty-six smaller cells. Note that each smaller cell is approximately ⅓ of a 6-inch standardized solar cell. For example, smaller cells 904, 906, and 908 are evenly divided portions of a standard-sized cell. Solar panel 900 is configured in such a way that every two adjacent rows of smaller cells are connected in series, forming three U-shaped strings. In FIG. 9, the top two rows of smaller cells are connected in series to form a first U-shaped solar string 902, the middle two rows of smaller cells are connected in series to form a second U-shaped solar string 910, and the bottom two rows of smaller cells are connected in series to form a third U-shaped solar string 912.

In the example shown in FIG. 9, solar module 900 includes three U-shaped strings each of which includes seventy-two smaller cells. The V_{oc} and I_{sc} of the string are 72V_{oc}_{_}_{cell} and I_{sc}_{_}_{cell}/3, respectively; and the V_{oc} and I_{sc} of the module are 72V_{oc}_{_}_{cell}, and I_{sc}_{_}_{cell}, respectively. Such module level V_{oc} and I_{sc} are similar to those of a conventional solar module of the same size with all its seventy-two cells connected in series, making it possible to adopt the same circuit equipment developed for the conventional modules.

Furthermore, the total internal resistance of panel 900 is significantly reduced. Assume that the internal resistance of a conventional cell is R_{cell}. The internal resistance of a smaller cell is Rₛₘₐₗₗ_{_}_{cell}=R_{cell}/3. In a conventional module with seventy-two conventional cells connected in series, the total internal resistance is 72 R_{cell}. In module 900 as illustrated in FIG. 9, each string has a total internal resistance R_{string}=72 Rₛₘₐₗₗ_{_}_{cell}=24 R_{cell}. Since module 900 has three U-shaped strings connected in parallel, the total internal resistance for module 900 is R_{string}/3=8 R_{cell}, which is 1/9 of the total internal resistance of a conventional module. As a result, the amount of power that can be extracted to external load can be significantly increased.

As described above, each of strings 902, 910, and 912 in module 900 includes seventy-two smaller cells connected in series. Each string may be connected to a corresponding bypass diode in an associated junction box (not shown in FIG. 9). For example, a first diode may have a first terminal that is connected to the positive (+) output of first string 902 and a second terminal that is connected to the negative (−) output of first string 902; a second diode may have a first terminal that is connected to the positive output of second string 910 and a second terminal that is connected to the negative output of second string 910; and a third diode may have a first terminal that is connected to the positive output of third string 912 and a second terminal that is connected to the negative output of third string 912. In the event that one of the solar cells includes a defective cell, the associated diode may serve to help bypass the current to prevent damage to solar module 900. For example, if one of the smaller cells in solar cell string 912 is defective, the third diode may help bypass the current that would have run through a properly functioning string 912. As another example, if one of the smaller cells in second string 910 is defective, the second diode may be engaged to help bypass the current that would have run through a properly functioning string 910.

Using one diode per seventy-two series-connected smaller cells in the example described above may, however, be overly burdensome. For example, a single diode may not be capable of handling the open-circuit voltage across seventy-two smaller solar cells. Moreover, the circuit arrangement of FIG. 9 may suffer from low efficiency since module 900 would effectively lose ⅓ of its solar conversion output if one or more of seventy-two smaller cells in any one of the three strings were defective.

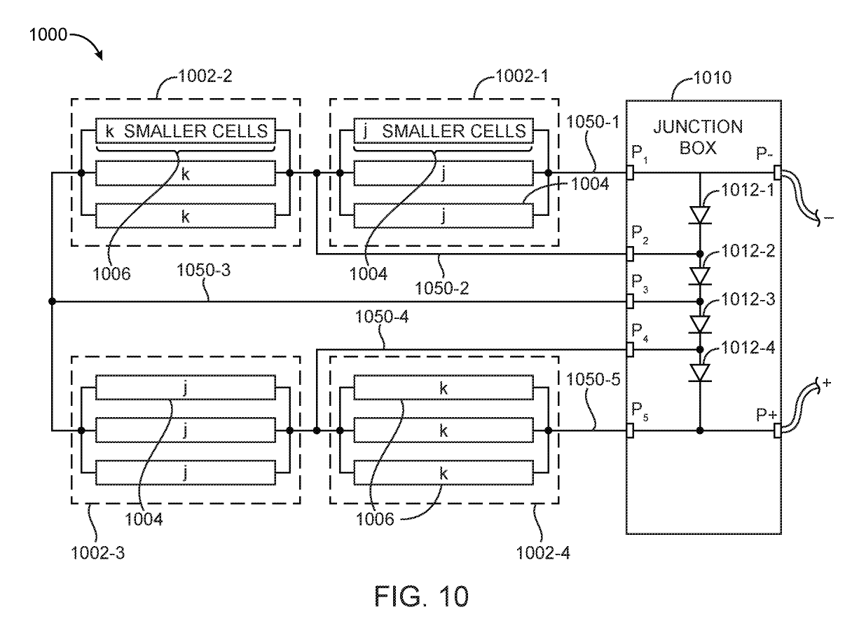

In accordance with an embodiment, FIG. 10 shows a diagram of an improved solar module configuration that reduces the number of solar cells that is connected across each bypass diode and helps reduce potential power loss. As shown in FIG. 10, solar module 1000 may include first sub-circuit 1002-1, second sub-circuit 1002-2, third sub-circuit 1002-3, and fourth sub-circuit 1002-4 that are coupled in series. Each sub-circuit 1002 may include multiple strings of solar cells coupled in parallel.

In the example of FIG. 10, sub-circuits 1002-1 and 1002-3 may each include three parallelly-coupled solar cell strings 1004 each of which include/series-connected smaller cells, whereas sub-circuits 1002-2 and 1002-4 may each include three parallelly-coupled solar cell strings 1006 each of which includes k series-connected smaller cells. As an example, j is equal to fifteen while k is equal to eighteen. As another example, j is equal to eighteen while k is equal to fifteen. As yet another example, j and k may be equal. These examples are merely illustrative. In general, j and k can be equal to any suitable integer. Each sub-circuit 1002 can also include any number of solar cell strings coupled in parallel.

Solar module 1000 may also include a junction box such as junction box 1010 that is coupled to sub-circuits 1002. In particular, junction box 1010 may include bypass diode components 1012 that are coupled to each of sub-circuits 1002 and may serve as an interface to an array inverter, which is configured to convert the DC current output from module 1000 to AC current. As shown in FIG. 10, junction box 1010 may have a negative output port P− and a positive output port P+ that are coupled to a corresponding array inverter via cables.

Each sub-circuit 1002 may be coupled in parallel with a respective bypass diode component 1012 in junction box 1010. Sub-circuit 1002-1 may have a first terminal that is coupled to first port P₁ of junction box 1010 via an interconnect bus 1050-1 and a second terminal that is coupled to second port P₂ of junction box 1010 via interconnect bus 1050-2. Sub-circuit 1002-2 may have a first terminal that is directly coupled to the second terminal of sub-circuit 1002-1 and a second terminal that is coupled to third port P₃ of junction box 1010 via interconnect bus 1050-3. Sub-circuit 1002-3 may have a first terminal that is directly coupled to the second terminal of sub-circuit 1002-2 and a second terminal that is coupled to fourth port P₄ of junction box 1010 via interconnect bus 1050-4. Sub-circuit 1002-4 may have a first terminal that is directly coupled to the second terminal of sub-circuit 1002-3 and a second terminal that is coupled to fifth port P₅ of junction box 1010 via interconnect bus 1050-5.

Junction box 1010 may include first bypass diode component 1012-1 coupled between ports P₁ and P₂, second bypass diode component 1012-2 coupled between ports P₂ and P₃, third bypass diode component 1012-3 coupled between ports P₃ and P₄, and fourth bypass diode component 1012-4 coupled between ports P₄ and P₅. Port P₁ may be shorted to negative port P−, whereas port P₅ may be shorted to positive port P+. Connected in this way, bypass diode 1012-1 can be coupled in parallel with sub-circuit 1002-1; bypass diode 1012-2 can be coupled in parallel with sub-circuit 1002-2; bypass diode 1012-3 can be coupled in parallel with sub-circuit 1002-3; and bypass diode 1012-4 can be coupled in parallel with sub-circuit 1002-4.

Connected in this way, diodes 1012-1, 1012-2, 1012-3, and 1012-4 may serve as current bypass components for sub-circuits 1002-1, 1002-2, 1002-3, and 1002-4, respectively. In this arrangement, diodes 1012 will only be exposed to the open-circuit voltage across each sub-circuit 1002, which is generally only a fraction of the long solar cell string of the type described in FIG. 9 (see, e.g., strings 902, 910, and 912). For example, string 902 of FIG. 9 may be coupled to a bypass diode that has to handle the open-circuit voltage of seventy-two smaller cells. In comparison, bypass diode 1012-1 of FIG. 10 may only have to handle the open-circuit voltage of fifteen smaller cells (assuming j is equal to fifteen) while bypass diode 1012-2 may only have to handle the open-circuit voltage of eighteen smaller cells (assuming k is equal to eighteen).

Moreover, reducing the length of each parallelly-connected string reduces the amount of power loss that is incurred when a random solar cell is defective. As described above in connection with FIG. 9, if any one of the smaller cells in one of strings 902, 910, and 912 is broken, solar module 900 loses one-third of its power output. In contrast, if one of the smaller cells in string 1004 of sub-circuit 1002-3 is broken, solar module 1000 would only lose approximately one-twelfth of its power output (assuming j and k are roughly equal and that each sub-circuit 1002 includes three parallel strings). The use of four series-connected sub-circuits 1002 thus provides a power savings of up to a factor of four compared to the embodiment of FIG. 9. If desired, solar module 1000 may be implemented using less than four sub-circuits such as including only two series-connected sub-circuits to provide power savings of up to a factor of two compared to the embodiment of FIG. 9 or using more than four sub-circuits such as including eight series-connected sub-circuits to provide power savings of up to a factor of eight compared to the embodiment of FIG. 9.

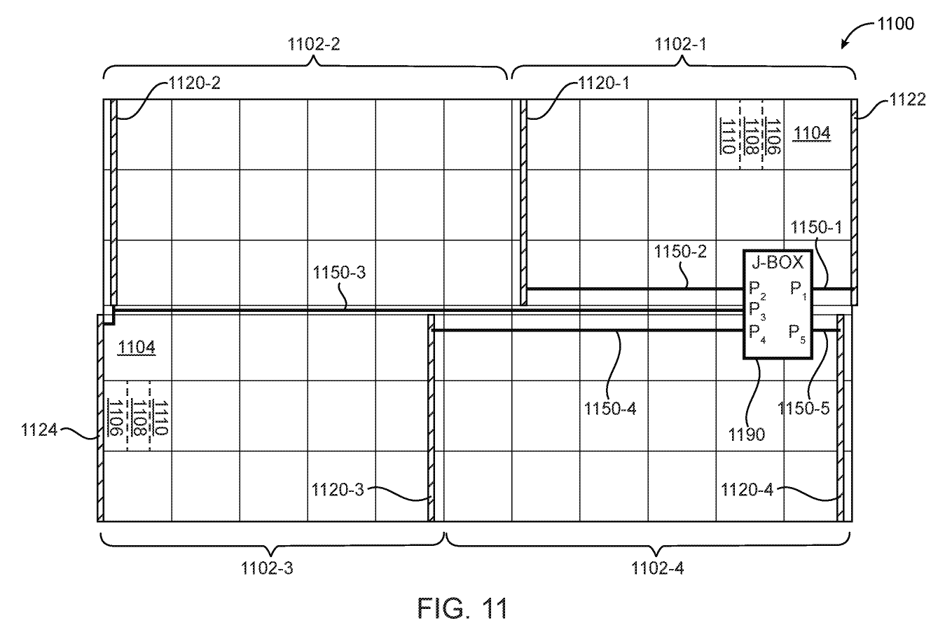

FIG. 11 is a diagram showing how the four sub-circuits in the exemplary solar module of FIG. 10 can be coupled to a junction box via straight interconnects from both sides of the junction box in accordance with an embodiment of the present invention. In particular, FIG. 11 shows a bottom view of solar module 1100. In the example of FIG. 11, solar module 1100 includes first sub-circuit 1102-1, second sub-circuit 1102-2, third sub-circuit 1102-3, and fourth sub-circuit 1102-4 that are coupled in series. Sub-circuits 1102-1 and 1102-3 may each include three strings of five series-connected, square-shaped solar cells 1104 coupled in parallel. Sub-circuits 1102-2 and 1102-4 may each include three strings of six series-connected, square-shaped solar cells 1104 coupled in parallel. Each square-shaped solar cell 1104 may be divided into three smaller cells 1106, 1108, and 1110 of the type described in FIGS. 8A and 8B.

The solar cells in module 1100 may be configured in the shingled layout. In the example of FIG. 11, all the smaller cells in sub-circuits 1102-1 and 1102-2 may be configured in a first shingle pattern having its right side on top, whereas all the smaller cells in sub-circuits 1102-1 may be configured in a second (reversed) shingled pattern having its left side on top, or vice versa. The smaller cells in each row are coupled to one another via edge busbars, which are not visible since the edges are overlapping.

At the right edge of sub-circuit 1102-1, extra wide metal tab 1122 couples together the top edge busbar of the leading smaller cells 1106 in the top three rows. At the left end of sub-circuit 1102-1, extra wide metal tab 1120-1 may be coupled to the conductive leads that are formed in smaller cells 1110 (see, e.g., conductive leads 820 of FIG. 8B) in the top three rows. At the left end of sub-circuit 1102-2, extra wide metal tab 1120-2 may be coupled to the conductive leads that are formed in smaller cells 1110 in the top three rows. Interconnected as such, metal tabs 1122, 1120-1, and 1120-2 couple strings 1104 and 1006 within sub-circuits 1002-1 and 1002-2 in parallel.

As described above, the shingled pattern of the bottom three rows may be reversed relative to the top three rows. At the left edge of sub-circuit 1102-3, extra wide metal tab 1124 couples together the bottom edge busbar of the leading smaller cells 1106 in the bottom three rows. At the right end of sub-circuit 1102-3, extra wide metal tab 1120-3 may be coupled to the conductive leads that are formed in smaller cells 1110 in the bottom three rows. At the right end of sub-circuit 1102-4, extra wide metal tab 1120-4 may be coupled to the conductive leads that are formed in smaller cells 1110 in the bottom three rows. Interconnected as such, metal tabs 1124, 1120-3, and 1120-4 couple strings 1104 and 1006 within sub-circuits 1002-3 and 1002-4 in parallel.

Still referring to FIG. 11, each of the metal tabs may be coupled to junction box 1190 via straight interconnect buses. As shown in FIG. 11, metal tab 1122 is coupled to port P₁ of junction box 1190 via straight bus 1150-1 (corresponding to path 1050-1 in FIG. 10); metal tab 1120-1 is coupled to port P₂ of junction box 1190 via straight bus 1150-2 (corresponding to path 1050-2 in FIG. 10); metal tabs 1120-2 and 1124 are coupled to port P₃ of junction box 1190 via straight bus 1150-3 (corresponding to path 1050-3 in FIG. 10); metal tab 1120-3 is coupled to port P₄ of junction box 1190 via straight bus 1150-4 (corresponding to path 1050-4 in FIG. 10); and metal tab 1120-4 is coupled to port P₅ of junction box 1190 via straight bus 1150-5 (corresponding to path 1050-5 in FIG. 10). This arrangement provides the shortest connection distance between each of the metal tabs and the respective ports of junction box 1190.

While straight wires may be desirable, the layout of FIG. 11 in which connections are made at two opposing sides of the junction box may hinder manufacturability. For example, junction box 1190 may have to be dropped at a precise location on the bottom surface of module 1100 in order to ensure that proper connections to the different junction box ports are made. This requirement may unnecessarily complicate module assembly.

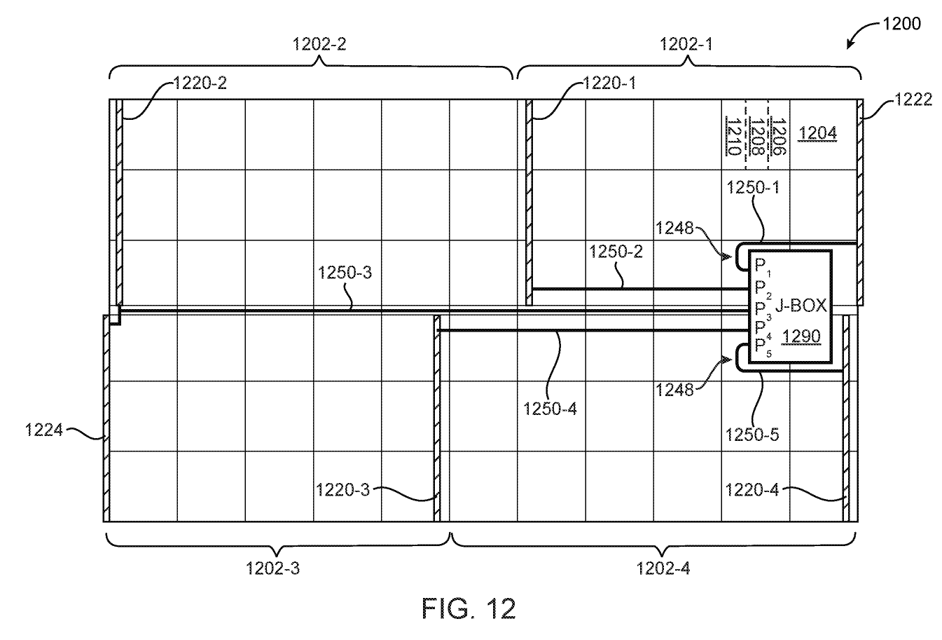

In accordance with an embodiment of the present invention, a solar module is provided where connections are only made to entry points formed along one side of a junction box, making the junction box much easier to install. FIG. 12 is a diagram showing how the four sub-circuits in the exemplary solar module of FIG. 10 can be coupled to a junction box 1290 to entry points from only one side (or edge of junction box 1290). The general module layout is similar to that of FIG. 11. Solar module 1200 may include sub-circuits 1202-1, 1202-2, 1202-3, and 1202-4, which correspond to sub-circuits 1102-1, 1102-2, 1102-3, and 1102-4 of FIG. 11, and will therefore not be described again in detail. Similarly, conductive tabs 1222, 1220-1, 1220-2, 1224, 1220-3, and 1220-4 correspond to tabs 1122, 1120-1, 1120-2, 1124, 1120-3, and 1120-4 of FIG. 11 and need not be described again in detail. Each square-shaped solar cell 1204 may include three smaller cells 1206, 1208, and 1210 configured in the shingled pattern.

As shown in FIG. 12, metal tab 1220-1 is coupled to port P₂ of junction box 1290 via straight bus 1250-2 (corresponding to path 1050-2 in FIG. 10); metal tabs 1220-2 and 1224 are coupled to port P₃ of junction box 1290 via straight bus 1250-3 (corresponding to path 1050-3 in FIG. 10); and metal tab 1220-3 is coupled to port P₄ of junction box 1290 via straight bus 1250-4 (corresponding to path 1050-4 in FIG. 10). To ensure that all of the solar module buses are connected to the left side of junction box 1290 (as viewed from the bottom orientation of FIG. 12), edge tabs 1222 and 1220-4—which are located to the right of junction box 1290—may be coupled to ports P₁ and P₅ via buses 1250-1 and 1250-2 that are routed around the top and bottom edges of junction box 1290 and fed back to the left edge of junction box 1290. Buses 1250-1 and 1250-5 may each have a U-shaped bending portion 1248 and can sometimes be referred to as a “J-bus.”

The formation of J-buses 1250-1 and 1250-5 therefore allows ports P₁ and P₅ to also be formed along the left edge of junction box 1290. Assembly operations can be greatly simplified when the module-level buses (e.g., buses 1250-1, 1250-2, 1250-3, 1250-4, and 1250-5) need to be connected to only one side of the junction box. The example of FIG. 12 in which the interconnect buses are coupled to the left edge of box 1290 is merely illustrative. In another suitable arrangement, the interconnect bus can be routed to only the top or bottom edge of junction box 1290 (e.g., by configuring wires 1250-1, 1250-2, 1250-3, 1250-4, and 1250-5 as L-shaped buses) to help improved manufacturability. In yet another suitable arrangement, the interconnect bus can be routed to only the right edge of junction box 1290 (e.g., by configuring wires 1250-2, 1250-3, and 1250-4 as J-shaped buses while leaving wires 1250-1 and 1250-5 as straight buses) to help improved manufacturability.

Typically, a solar module is subject to a lamination process prior to attachment of the junction box. During lamination, heat and pressure may be applied to seal the solar cells in place. For example, the solar module by be cured within an oven that is raised to 150° C. or more and may be subject to pressure of above 1.0 atmospheres. Moreover, each solar module may be put through a temperature cycling test that varies temperature between −40° C. and +85° C. to ensure that the solar module can operate properly within typical operating ranges.

Temperature change that arises during lamination and temperature cycling tests and also wide temperature variations during normal operation of the solar module can (e.g., the temperature difference between night and day), however, introduce high thermal stress to electrical structures within a solar module. For example, the expansion and contraction resulting from increases and decreases in temperature may introduce mechanical stress that can potentially cause some of the longer module-level interconnect buses (e.g., interconnect wires 1250-2, 1250-3, and 1250-4 in FIG. 12) to crack or even break, which can sometimes result in inadvertent short or open circuits.

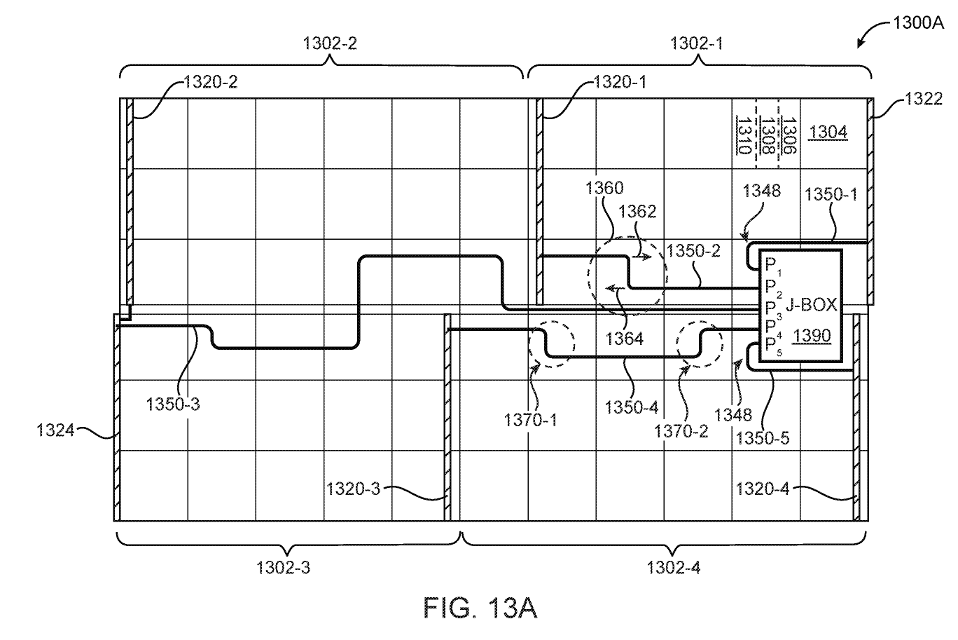

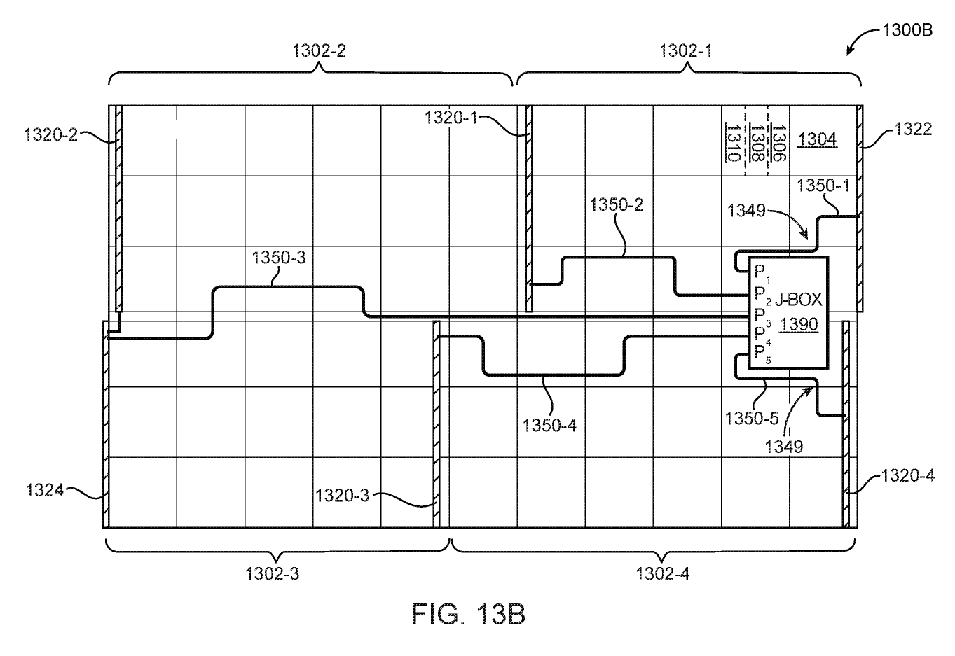

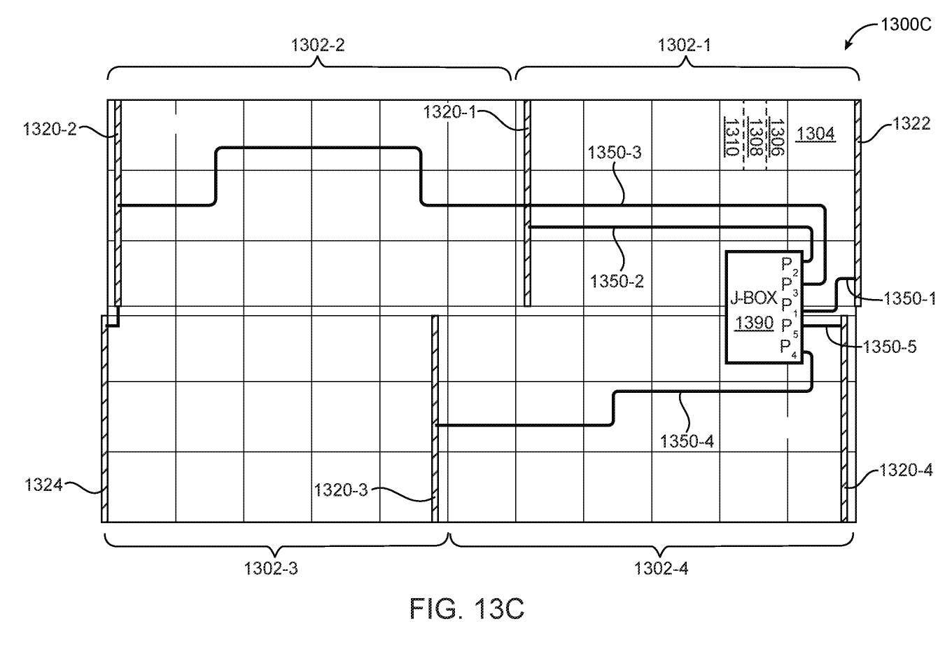

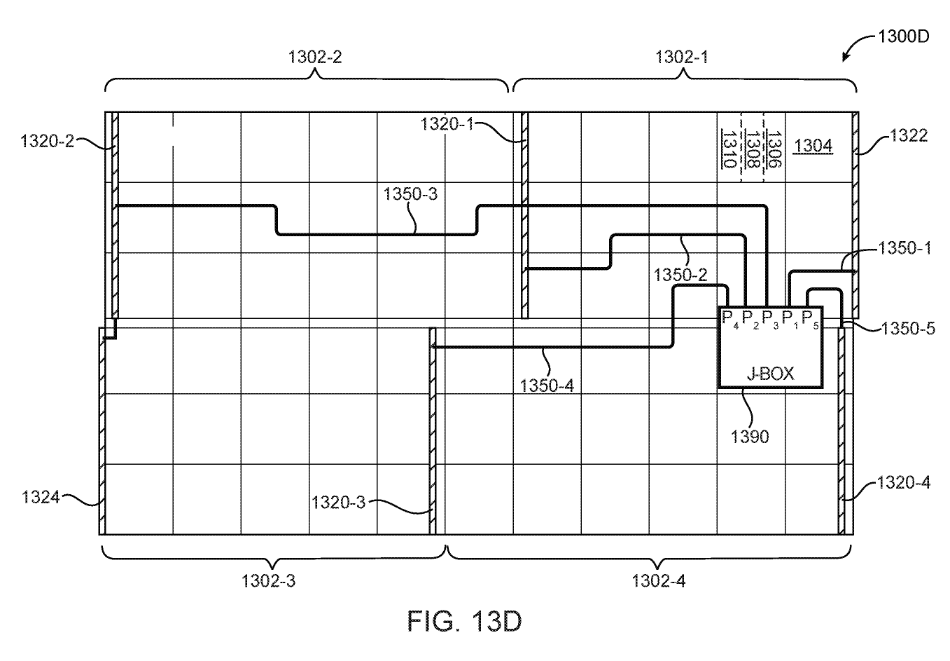

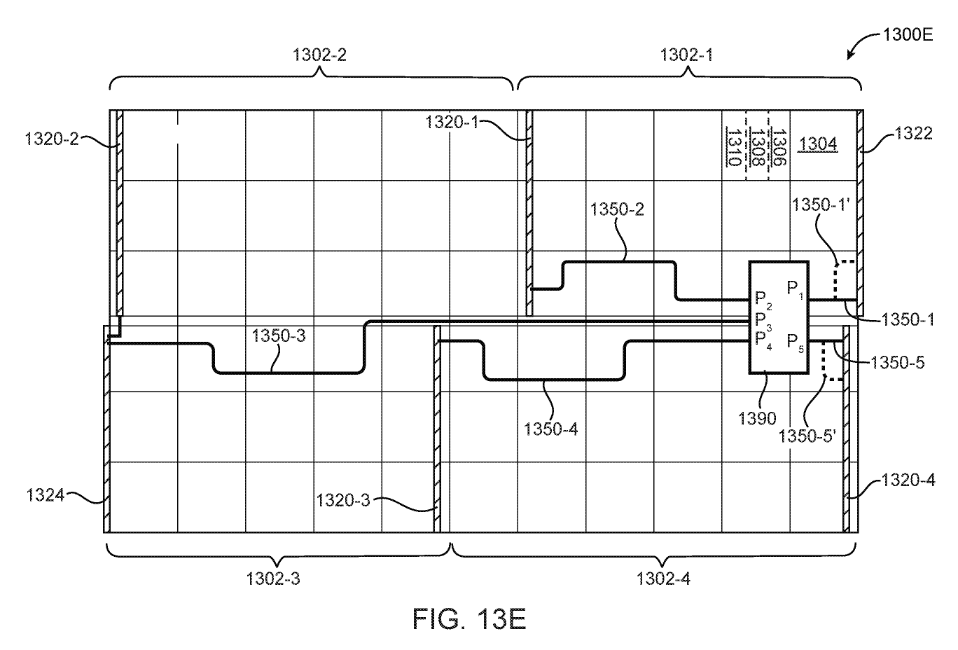

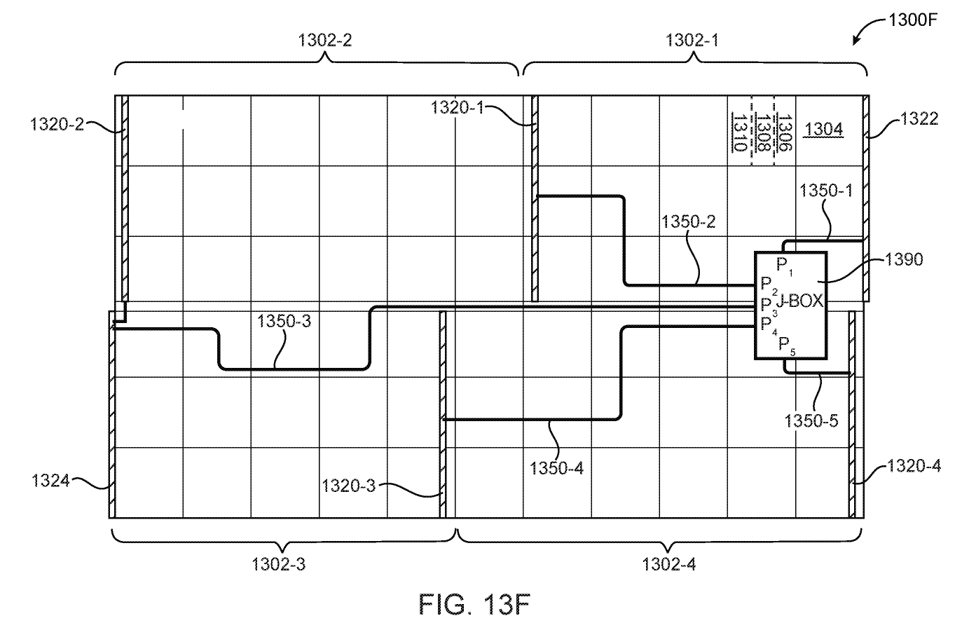

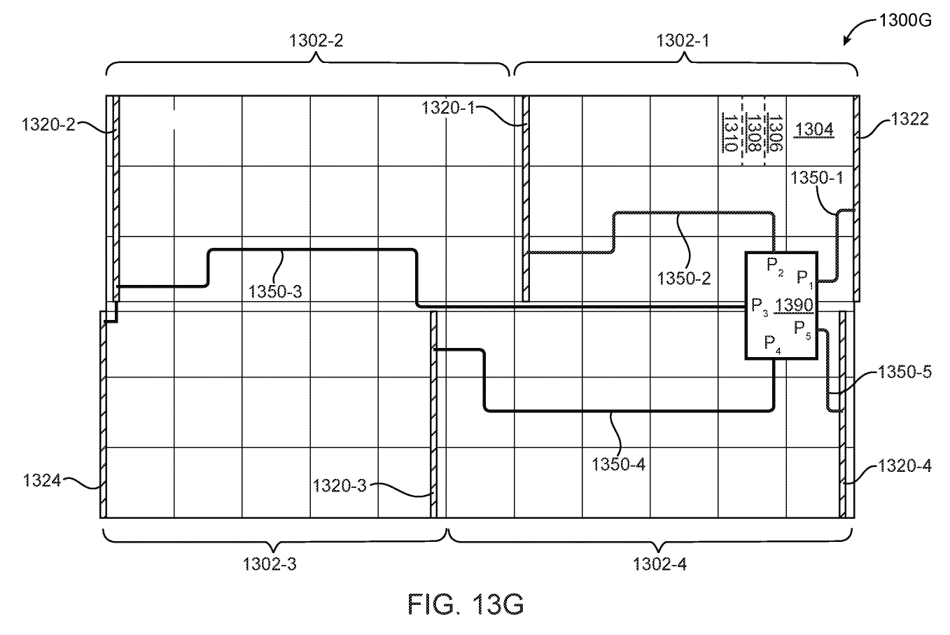

In an effort to prevent such faults, a solar module may be provided with strain relief features which help mitigate the chances of mechanical failures when high thermal stress is applied. FIG. 13A is a diagram showing how the four sub-circuits in the exemplary solar module of FIG. 10 can be coupled to junction box 1390 from only one side of the junction box via interconnects with multiple bends to help provide strain relief in accordance with an embodiment of the present invention. The general layout of module 1300 is similar to that of FIG. 12. Solar module 1300A may include sub-circuits 1302-1, 1302-2, 1302-3, and 1302-4, which correspond to sub-circuits 1202-1, 1202-2, 1202-3, and 1202-4 of FIG. 12. Similarly, conductive tabs 1322, 1320-1, 1320-2, 1324, 1320-3, and 1320-4 correspond to tabs 1222, 1220-1, 1220-2, 1224, 1220-3, and 1220-4 of FIG. 12. Each square-shaped solar cell 1304 may include three smaller cells 1306, 1308, and 1310 configured in the shingled pattern.

As shown in FIG. 13A, metal tab 1322 may be coupled to port P₁ of junction box 1390 via first J-bus 1350-1 with U-shaped bend 1348, whereas metal tab 1320-4 may be coupled to port P₅ of junction box 1390 via second J-bus 1350-5 with U-shaped bend 1348. In the example of FIG. 13, metal tab 1320-1 may be coupled to port P₂ of junction box 1390 via interconnect bus 1350-2 (corresponding to path 1050-2 in FIG. 10) that includes a first bending portion 1360 having two bends such that bus 1350-2 has two parallel segments that are joined by an intermediate segment that extends perpendicular to the two parallel segments (i.e., the intermediate segment is interposed between the two bends in portion 1360). These bends may provide strain relief or “slack” such that bus 1350-2 can freely expand/contract in the direction of arrows 1362 and 1364 during changes in temperature. Configured in this way, the longer module-level interconnect buses are more mechanically robust and resistant to thermal stress. In general, an interconnect bus with one or more bends has a length that is greater than the distance between its two terminals.

The example of bus 1350-2 having two bends is merely illustrative. Metal tab 1320-3 may be coupled to port P₄ of junction box 1390 via interconnect bus 1350-4 (corresponding to path 1050-4 in FIG. 10) that includes a first bending portion 1370-1 and a second bending portion 1370-2. First bending portion 1370-1 may include two bends having an intermediate segment joining and extending perpendicular to two parallel segments. Similarly, second bending portion 1370-2 may also include two bends having an intermediate segment joining and extending perpendicular to two parallel segments. Two bending portions can potentially provide more strain relief than only one bending portion.

Stiff referring to FIG. 13A, metal tab 1324, which is also shorted with metal tab 1320-2, may be coupled to port P₃ of junction box 1390 via interconnect bus 1350-3 (corresponding to path 1050-4 of FIG. 10). In the example of FIG. 10, path 1350-3 includes six bends overall. In general, each bus 1350-1, 1350-2, 1350-3, 1350-4, and 1350-5 may be provided with any suitable number bends. As examples, each bus 1350 may include two or more bends, four or more bends, eight or more bends, only one bend, or may have no bends at all. The number of bends in a given path may also depend on its length. For example, a longer path may be provided with more bends for additional strain relief, whereas a relatively shorter path may be provided with fewer bends to help reduce complexity. Each bend may be curved or formed at other suitable angles (e.g., two segments may be joined at 90°, 60°, 45°, 30°, etc.).

The embodiment of FIG. 13A configured as such can therefore provide: (1) improved ease of assembly since all the module-level buses are coupled to only one side of the junction box and (2) strain relief to mitigate the thermal stress introduced by temperature variations during manufacturing and during normal use of the panel by including multiple bends in the module-level buses.

FIG. 13B shows another suitable arrangement of a solar module 1300B. Solar module 1300B may be similar to solar module 1300A of FIG. 13A, but solar module 1300B may include J-buses 1350-1 and 1350-2 each of which are provided with additional bends 1349 to provide further strain relief. In contrast to FIG. 13A, each of paths 1350-2, 1350-3, and 1350-4 in the exemplary solar module 1300B of FIG. 13B includes the same number of bends. As described above, each individual interconnect bus may be provided with any suitable number of bends to provide the desired amount of stress relief.

The embodiments of FIGS. 13A and 13B in which the module-level interconnect paths are connected to the left edge of junction box 1390 is merely illustrative and does not serve to limit the scope of the present invention. FIG. 13C shows another suitable arrangement in which the module-level interconnect buses are coupled to only the right edge of junction box 1390. As shown in FIG. 13C, interconnect 1350-1 that couples conductive tab 1322 to port P₁ of junction box 1390 may include a couple of bends; interconnect 1350-2 that couples conductive tab 1320-1 to port P₂ of junction box 1390 may be a J-bus that includes a U-shaped bend; interconnect 1350-3 that couples conductive tab 1320-2, which is also shorted to tab 1324, to port P₃ of junction box 1390 may also be a J-bus that includes multiple bends in additional to a U-shaped bend; interconnect 1350-4 that couples conductive tab 1320-3 to port P₄ of junction box 1390 may also be a J-bus that includes multiple bends in additional to a U-shaped bend; and interconnect 1350-5 that couples conductive tab 1320-4 to port P₅ of junction box 1390 may be straight. This is merely illustrative. If desired, interconnect 1350-1 may also be straight, interconnect 1350-5 may also include one or more bends, and/or interconnect 1350-2 may also be provided with additional strain-relief bends.

In yet another suitable arrangement, FIG. 13D shows how the interconnect buses may be coupled to only a top edge of junction box 1390 (as viewed from the orientation of FIG. 13D). As shown in FIG. 13D, interconnect 1350-1 that couples conductive tab 1322 to port P₁ of junction box 1390 may include only one bend (e.g., an L-shaped bend); interconnect 1350-2 that couples conductive tab 1320-1 to port P₂ of junction box 1390 may include multiple strain-relief bends in additional to an L-shaped bend; interconnect 1350-3 that couples conductive tab 1320-2, which is also shorted to tab 1324, to port P₃ of junction box 1390 may also include multiple strain-relief bends in additional to an L-shaped bend; interconnect 1350-4 that couples conductive tab 1320-3 to port P₄ of junction box 1390 may also include multiple strain-relief bends in additional to an L-shaped bend; and interconnect 1350-5 that couples conductive tab 1320-4 to port P₅ of junction box 1390 may be a J-bus with a U-shaped bend. This is merely illustrative. If desired, each interconnect 1350 may be provided with more or fewer strain-relief bends. In an alternate embodiment, the interconnect buses may also be routed to only the bottom edge of junction box 1390.

Bus strain-relief features may also be provided for solar module with junction boxes having ports at two or more sides. As shown in FIG. 13E, interconnect buses 1350-2, 1350-3, and 1350-4 with multiple strain-relief bends may be coupled to ports P₂-P₄ of junction box 1390 from the left side, whereas interconnect buses 1350-1 and 1350-5 may be coupled to ports P₁ and P₅ of junction box 1390 from the right side. The example of FIG. 13E illustrate buses 1350-1 and 1350-5 as being straight. This is merely illustrative. If desired, buses 1350-1 and 1350-5 may also be provided with additional strain-relief bends, as shown by dotted paths 1350-1′ and 1350-2′.

In yet another suitable configuration, the interconnect buses may be routed to three different edges of junction box 1390 (see, e.g., FIG. 13F). As shown in FIG. 13F, interconnect 1350-1 having an L-shaped bend may be coupled to the upper edge of junction box 1390; interconnects 1350-2, 1350-3, and 1350-4 having multipole strain-relief bends may be coupled to the ledge edge of junction; and interconnect 1350-5 having an L-shaped bend may be coupled to the lower edge of junction box 1390. This is merely illustrative. If desired, each of the interconnect buses 1350 may be provided with more or fewer thermal strain-relieving bends.

In yet another suitable configuration, the interconnect buses may be routed to all four different edges of junction box 1390 (see, e.g., FIG. 13G). As shown in FIG. 13G, interconnect buses 1350-1 and 1350-2 having L-shaped bends may be coupled to the left side of junction box 1390; interconnect 1350-2 having three bends may be coupled to the top side of junction box 1390; interconnect 1350-3 having four bends may be coupled to the left side of junction box 1390; and interconnect 1350-4 having three bends may be coupled to the bottom side of junction box 1390. This is merely illustrative. If desired, each of the interconnect buses 1350 may be provided with more or fewer thermal strain-relieving bends.

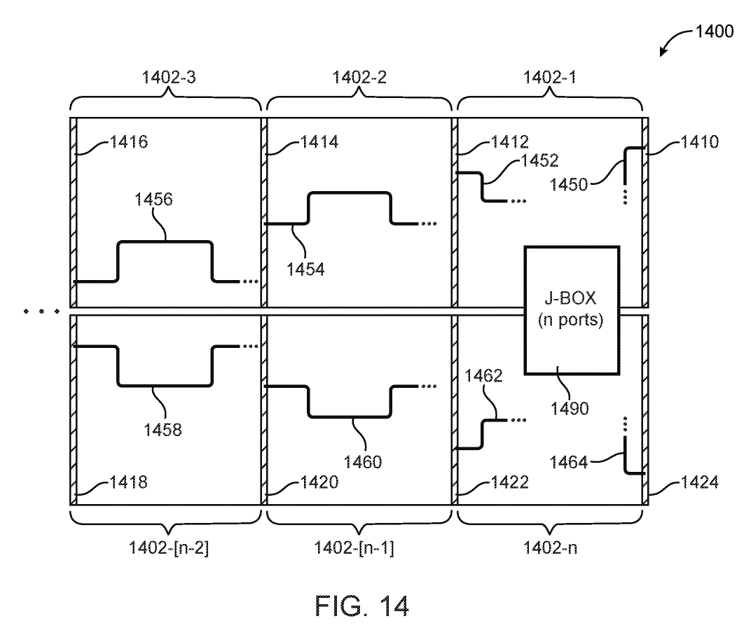

The embodiments of FIGS. 10-13 in which the solar module is divided into four sub-circuits is merely exemplary and are not intended to limit the scope of the present invention. In general, a solar module may be divided into n sub-circuits, where n may be equal to 2, 3, 4, 5, 6, 7, 8, or other suitable integers. FIG. 14 shows a general layout for such a solar module 1400. As shown in FIG. 14, solar module 1400 may include a first sub-circuit 1402-1, a second sub-circuit 1402-2, a third sub-circuit 1402-3, . . . , and an nth sub-circuit 1402-n. These n sub-circuits 1402 may be interconnected using conductive tabs such as conductive tabs 1410, 1412, 1414, 1416, 1418, 1420, and 1422.

Still referring to FIG. 14, each of the conductive tabs may be coupled to a corresponding port in junction box 1490. For example, conductive tab 1410 may be coupled to a corresponding port in box 1490 via interconnect bus 1450; conductive tab 1412 may be coupled to a corresponding port in box 1490 via interconnect bus 1452; conductive tab 1414 may be coupled to a corresponding port in box 1490 via interconnect bus 1454; conductive tab 1416 may be coupled to a corresponding port in box 1490 via interconnect bus 1456; conductive tab 1418 may be coupled to a corresponding port in box 1490 via interconnect bus 1458; conductive tab 1460 may be coupled to a corresponding port in box 1490 via interconnect bus 1460; and conductive tab 1462 may be coupled to a corresponding port in box 1490 via interconnect bus 1462.

Each of the interconnect buses (e.g., interconnect paths 1450, 1452, 1454, 1456, 1458, 1460, and 1462) may include one or more strain-relieving bends, one or more J-bends, one or more L-shaped bends, etc. These interconnects may be coupled to only entry points formed along one side of junction box 1490, entry points formed along any two sides of junction box 1490, entry points formed along any three sides of junction box 1490, or entry points formed along all four sides of junction box 1490. In general, junction box 1490 may be attached to an edge of solar panel 1400. If desired, however, junction box 1490 may be placed in the center of solar panel 1400 or at other intermediate locations to facilitate routing to each of the different sub-circuits.

The foregoing is merely illustrative of the principles of this invention and various modifications can be made by those skilled in the art without departing from the scope and spirit of the invention. The foregoing embodiments may be implemented individually or in any combination. Additionally, the above disclosure is not intended to limit the present invention.

1. A solar module, comprising:
a first edge, and a second edge opposite the first edge
a plurality of sub-circuits between the first edge and the second edge;
a junction box positioned between the first edge and the second edge, the junction box comprising a first side facing the first edge; and
interconnect buses connecting the plurality of sub-circuits to the junction box, wherein the interconnect buses comprise a first interconnect bus comprising:
a first portion extending from the first side of the junction box toward the first edge of the solar module;
a second portion; and
a bend, wherein the bend is located between the first and second portions and the second portion extends from the bend toward the second edge.

2. The solar module of claim 1, wherein the at least one of the interconnect buses has a first terminal and a second terminal and has a length that is greater than the distance between its first and second terminals.

3. The solar module of claim 1, wherein at least one of the interconnect buses has a U-shaped bend.

4. The solar module of claim 1, wherein at least two of the interconnect buses have a U-shaped bend.

5. The solar module of claim 1, wherein the interconnect buses comprise a second interconnect bus comprising:
a first straight portion extending in a first direction perpendicular to the first edge;
a second straight portion extending perpendicular to the first direction;
a first bend connecting the first straight portion and the second straight portion;
a third straight portion extending parallel to the first direction; and
a second bend connecting the second straight portion and the third straight portion, wherein the third straight portion extends from the second bend toward the first edge.

6. The solar module of claim 1, wherein the interconnect buses comprise a second interconnect bus comprising:
a first straight portion extending in a first direction perpendicular to the first edge;
a second straight portion extending in a second direction perpendicular to the first direction;
a first bend connecting the first straight portion and the second straight portion;
a third straight portion extending parallel to the first direction;
a second bend connecting the second straight portion and the third straight portion, wherein the third straight portion extends from the second bend, away from the first straight portion and toward the first edge;
a fourth straight portion extending parallel to the second direction;
a third bend connecting the third straight portion and the fourth straight portion;
a fifth straight portion extending parallel to the first direction; and
a fourth bend connecting the fourth straight portion and the fifth straight portion, wherein the first straight portion extends from the fourth bend toward the first edge.

7. The solar module of claim 1, wherein one of the interconnect buses has a different number of bends than another one of the interconnect buses.

8. The solar module of claim 1, wherein each sub-circuit in the plurality of sub-circuits comprises multiple solar cell strings coupled in parallel.

9. A method for fabricating a solar module, comprising:
coupling a plurality of solar cells in series to form a solar cell string;
coupling multiple solar cell strings in parallel to form a sub-circuit;
coupling multiple sub-circuits in series;
positioning the multiple sub-circuits between a first edge of the solar module, and a second edge, opposite the first edge, of the solar module;
positioning a junction box between the first and second edges, the junction box comprising a first side positioned to face the first edge; and
routing the sub-circuits to the junction box via a plurality of interconnect buses, wherein the interconnect buses comprise a first interconnect bus comprising:
a first portion extending from the first side of the junction box toward the first edge of the solar module;
a second portion; and
a bend, wherein the bend is located between the first and second portions and the second portion extends from the bend toward the second edge.

10. The method of claim 9, wherein at least two of the interconnect buses have the same number of bends.

11. The method of claim 9, wherein at least two of the interconnect buses have a different number of bends.

12. The method of claim 9, wherein the solar module includes four sub-circuits that are coupled to five ports of the junction box.

13. The method of claim 9, wherein at least one of the interconnect buses comprises:
a first straight portion extending in a first direction perpendicular to the first edge;
a second straight portion extending perpendicular to the first direction;
a first bend connecting the first straight portion and the second straight portion;
a third straight portion extending parallel to the first direction; and
a second bend connecting the second straight portion and the third straight portion, wherein the third straight portion extends from the second bend toward the first edge.

14. The method of claim 9, further comprising:
providing the at least one of the interconnect buses with at least two bends between at least three straight portion configured so that the at least one interconnect bus can freely expand during a temperature change.

15. The method of claim 9, wherein the at least one of the interconnect buses has a first terminal and a second terminal and has a length that is greater than the distance between its first and second terminals.

16. A solar module, comprising:
first edge, and a second edge opposite the first edge;
a plurality of sub-circuits between the first edge and the second edge;
a junction box positioned between the first edge and the second edge, the junction box comprising a first side facing the first edge; and
interconnect buses connecting the plurality of sub-circuits to the junction box, wherein the interconnect buses comprise a first interconnect bus comprising:
comprises a first straight portion extending in a first direction toward the first edge;
a second straight portion extending perpendicular to the first direction; a first bend connecting the first straight portion and the second straight portion;
a third straight portion extending parallel to the first direction; and a second bend connecting the second straight portion and the third straight portion, wherein the third straight portion extends from the second bend toward the first edge.

17. The solar module of claim 16, wherein the first and second bends are configured to be strain-relieving bends.

18. The solar module of claim 17, wherein the interconnect buses connect the plurality of sub-circuits to entry points from at least two sides of the junction box.

19. The solar module of claim 17, wherein of interconnect buses connect the plurality of sub-circuits to entry points from at least three or more sides of the junction box.

20. The solar module of claim 16, wherein the solar panel includes n sub-circuits, and wherein the junction box has n+1 ports that are coupled to the sub-circuits via the interconnect buses.
